(19) United States
(12) Patent Application Publication
(10) Pub. No.: US 2026/0351154 A1
(43) Pub. Date: Nov. 5, 2026

(54) SPATIAL AND TEMPORAL DITHER FOR LASER BEAM SCANNING DISPLAY SYSTEMS IN WEARABLE DEVICES

(71) Applicant: GOOGLE LLC, Mountain View, CA (US)

(72) Inventors: Stephen Karl Swartzentruber, Kitchener (CA); Stuart James Myron Nicholson, Waterloo (CA); Ali Elwazir, Kitchener (CA); Bergen Fletcher, St. Jacobs (CA); Daniel Malea, Waterloo (CA)

(21) Appl. No.: 19/105,111

(22) PCT Filed: Aug. 24, 2022
(86) PCT No.: PCT/US2022/041393

§ 371 Date: Feb. 20, 2025

(51) Int. Cl. G09G 3/20; G02B 27/01; G09G 3/00; G09G 3/22

(52) U.S. Cl. CPC G09G 3/2044; G02B 27/0172; G09G 3/001; G09G 3/22; G02B 2027/0178

(57) ABSTRACT

The present disclosure provides techniques to expand the dynamic range of laser output intensity in a laser beam scanning (LBS) display system for a wearable head mounted device (WHMD). A laser controller controls the lasers to alternate between two laser drive levels in a series of laser pulses to emit light at a duty-cycled intensity corresponding to a target pixel intensity. The user perceives the duty-cycled intensity as the target pixel intensity when viewing the image. Accordingly, the methods and apparatuses provided herein are able to achieve a higher number of pixel display intensities in the images as perceived by the user without increasing the number of laser drive levels.

### BACKGROUND

Some wearable head mounted displays (WHMDs) employ laser beam scanning (LBS) display systems to display images for a user. LBS display systems in augmented reality (AR) applications, for example, project images onto a user's eyes using a combination of red, green, and blue lasers. The output intensity of each of the lasers is related to an input current, which is controlled by a laser drive level. However, conventional LBS display systems can have limited dynamic range, negatively impacting the user experience.

### SUMMARY

The present disclosure describes embodiments for expanding the dynamic range of laser output intensity in an LBS system for a WHMD by controlling a laser to alternate between two laser drive levels in a series of laser pulses to emit light, as perceived by the user of the WMHD, at an intermediate intensity between the two laser drive levels.

In one example embodiment, a laser controller for a wearable head mounted display (WHMD) is configured to identify a first laser drive level and a second laser drive level based on a pixel display intensity for displaying an image. The laser controller is further configured to control a laser to alternate between the first laser drive level and the second laser drive level in a series of laser pulses to emit light at a duty-cycled intensity corresponding to the pixel display intensity.

In some embodiments, the laser controller is further configured to retrieve at least one of the first laser drive level or the second laser drive level from a lookup table storing values for a plurality of laser drive levels and corresponding pixel display intensities. In some embodiments, the at least one of the first laser drive level or the second laser drive level are identified from the lookup table based on the first laser drive level having a corresponding first pixel display intensity above the pixel display intensity or the second laser drive level having a corresponding second pixel display intensity below the pixel display intensity. In some embodiments, emitting light at the duty-cycled intensity includes operating the laser at the first laser drive level for a first non-contiguous portion of a duty cycle and operating the laser at the second drive level for a second non-contiguous portion of the duty cycle, wherein a duration of the first non-contiguous portion relative to a duration of the second non-contiguous portion produces the duty-cycled intensity corresponding to the pixel display intensity. For example, in some embodiments, the duration of the first period and the duration of the second period are equal, and in other embodiments, the duration of the first period and the duration of the second period are not equal. In some embodiments, the duty cycle corresponds to a noise mask selected from a table of noise masks, wherein the noise mask includes a grid mapped to pixels in an image display area of the WHMD, and the grid includes a first subset of values corresponding to the first laser drive level and a second subset of values corresponding to the second laser drive level. In some embodiments, the noise mask is tiled across the image display area of the WHMD. In some embodiments, the laser controller is further configured to shift the noise mask by an offset in at least one of a first direction or a second direction of the image display area for subsequent laser pulses in the series of laser pulses. In some embodiments, the laser controller is further configured to supply a current to the laser to control an output intensity of the laser, wherein a laser drive level of the laser is split into a first region characterized by a linear relationship between the supply current and the output intensity and a second region below the first region that does not follow the linear relationship. In some embodiments, the laser controller is further configured to control the laser to mimic operation of an output intensity in the second region by alternating between the first laser drive level and the second laser drive level, wherein the first laser drive level corresponds to a minimum laser drive level in the first region and the second laser drive level corresponds to a non-lasing state in which the laser does not emit light.

In another example embodiment, a laser beam scanner for a WHMD includes one or more lasers each configured to emit light of a particular color, and a laser controller configured to identify, for at least one of the one or more lasers, a first laser drive level and a second laser drive level based on a pixel display intensity for displaying an image, and control the at least one of the one or more lasers to alternate between the first laser drive level and the second laser drive level in a series of laser pulses to emit light at a duty-cycled intensity corresponding to the pixel display intensity.

In some embodiments, for the laser beam scanner, at least one of the first laser drive level or the second laser drive level are identified from the lookup table based on the first laser drive level having a corresponding first pixel display intensity above the pixel display intensity and the second laser drive level having a corresponding second pixel display intensity below the pixel display intensity. In some embodiments, the emitting of light at the duty-cycled intensity includes operating the at least one of the one or more lasers at the first laser drive level for a first period of a duty cycle and operating the at least one of the one or more lasers at the second drive level for a second period of the duty cycle, wherein a duration of the first portion relative to a duration of the second portion produces the duty-cycled intensity corresponding to the pixel display intensity. In some embodiments, the duty cycle corresponds to a noise mask selected from a table of noise masks, wherein the noise mask includes a grid mapped to pixels in an image display area of the WHMD, and wherein the grid includes a first subset of values corresponding to the first laser drive level and a second subset of values corresponding to the second laser drive level. In some embodiments, the laser controller in the laser beam scanner is configured to shift the noise mask by an offset in at least one of a first direction or a second direction of the image display area for subsequent laser pulses in the series of laser pulses.

In another example embodiment, a method includes identifying a first laser drive level and a second laser drive level based on a pixel display intensity for displaying an image and controlling a laser to alternate between the first laser drive level and the second laser drive level in a series of laser pulses to emit light at a duty-cycled intensity corresponding to the pixel display intensity.

In some embodiments, the method includes retrieving at least one of the first laser drive level or the second laser drive level from a lookup table storing values for a plurality of laser drive levels and corresponding pixel display intensities. In some embodiments, the first laser drive level or the second laser drive level are identified from the lookup table based on the first laser drive level having a corresponding first pixel display intensity above the pixel display intensity or the second laser drive level having a corresponding second pixel display intensity below the pixel display intensity. In some embodiments, displaying the image at the duty-cycled intensity includes operating the laser at the first laser drive level for a first period of a duty cycle and operating the laser at the second drive level for a second period of the duty cycle, wherein a duration of the first portion relative to a duration of the second portion produces the duty-cycled intensity corresponding to the pixel display intensity.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 shows an example display system having a support structure that houses a projection system configured to project images toward the eye of a user, in accordance with some embodiments.

FIG. 2 shows an example of a block diagram of a projection system that projects light representing images onto the eye of a user via a display system, such as the display system of FIG. 1, in accordance with some embodiments.

FIG. 3 shows an example of a block diagram of a laser beam scanning (LBS) display system, in accordance with some embodiments.

FIG. 4 shows an example of a graph illustrating the stimulated emission region and spontaneous emission region of a laser, in accordance with some embodiments.

FIG. 5 shows an example of a series of graphs illustrating the target output pixel intensity of light emitted by a laser by combining an integer-based laser drive level of an LDD with a fractional-based duty cycle, in accordance with some embodiments.

FIG. 6 shows an example of a graph illustrating parameters that are used to implement dithering techniques, in accordance with some embodiments.

FIG. 7 shows an example of a block diagram of a dither pipeline to determine a dither drive level, a base drive level, and a duty cycle based on a target pixel display intensity, in accordance with some embodiments.

FIG. 8 shows an example of a dither tile corresponding to a duty cycle for applying spatial dither to an image, in accordance with some embodiments.

FIG. 9 shows an example of a dither tile offset for applying temporal dither to the dither tile shown in FIG. 8, in accordance with some embodiments.

FIG. 10 shows an example of a flowchart illustrating a method for controlling a laser, in accordance with some embodiments.

### DETAILED DESCRIPTION

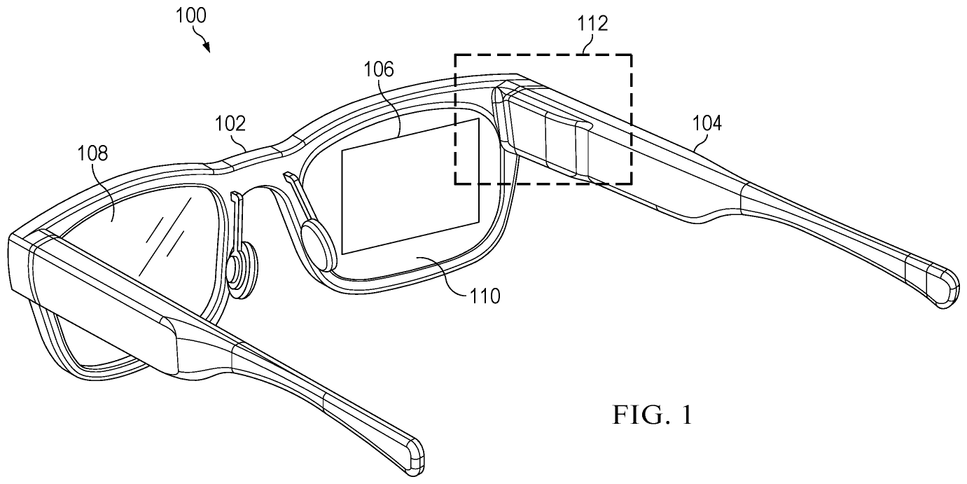

In a WHMD with an LBS display system, the brightness or intensity of the image projected to the user is limited by the physics of the lasers and by the amount of color depth provided by laser diode drivers (LDDs) based on their corresponding laser drive levels. For example, conventional LBS display systems are generally limited to controlling lasers in a stable region above a minimum laser operation threshold at which the output intensity of the laser is governed by a linear relationship between the input current to the laser and the output intensity of the light emitted by the laser. Furthermore, the output intensity of the light emitted by the lasers in the stable region is limited by the granularity of the laser drive levels of the LDD. FIGS. 1-10 illustrate techniques to expand the dynamic range of the laser output intensity in an LBS display system for a WHMD using spatial and temporal dither, thereby improving the overall user experience.

To illustrate, a laser controller of a WMHD is configured to identify a first laser drive level and a second laser drive level for a laser based on a pixel display intensity for displaying an image. The image to be displayed has, in some embodiments, three light color components, e.g., red, green, and blue, that are each emitted by a laser of the respective color. For example, a red laser emits red light at the red pixel display intensity to provide the red color portion of the image. The laser controller is configured to control each of the lasers to alternate between a first laser drive level and second laser drive level in a series of laser pulses to emit light at a duty-cycled intensity corresponding to the pixel display intensity. Accordingly, the laser controller implements dithering techniques across a series of frames to approximate the target pixel display intensity over time. The controller alternates the laser drive levels at a rate such that the user is unable to perceive the switches between laser drive levels and instead perceives the resulting image as if it were being displayed at the target pixel display intensity.

In this manner, the techniques of the present disclosure increase the dynamic range of the output intensity of an LBS display system of a WHMD by alternating between two available laser drive levels such that the viewer perceives the resulting image with an “intermediate” pixel intensity (also referred to as the duty-cycled intensity). The dynamic range of the output intensity of the LBS display system is increased since the laser controller controls the laser(s) to mimic operation at laser drive levels that the laser(s) otherwise would not be able to operate at. For example, in some embodiments, a laser mimics operation in the unstable region below the minimum laser operation threshold by alternating between a laser drive level at the minimum laser operation threshold (referred to as a minimum laser drive level) and a non-lasing state drive level in which the laser does not emit light. In another example, in some embodiments, the laser mimics operation between two laser drive levels in the stable region to increase the color depth of the image displayed to the user. Accordingly, the same number of laser drive levels are able to provide a higher range of pixel display intensities in the image as perceived by the user of the WMHD.

FIGS. 1-10 illustrate embodiments of an example display system and techniques to extend the dynamic range of LBS display systems in WHMDs. However, it will be appreciated that the apparatuses and techniques of the present disclosure are not limited to implementation in this particular display system, but instead may be implemented in any of a variety of display systems using the guidelines provided herein.

FIG. 1 illustrates an example display system 100 having a support structure 102 that includes an arm 104, which houses a laser projection system configured to project images toward the eye of a user, such that the user perceives the projected images as being displayed in a field of view (FOV) area 106 of a display at one or both of lens elements 108, 110. In the depicted embodiment, the display system 100 is a WHMD that includes a support structure 102 configured to be worn on the head of a user and has a general shape and appearance of an eyeglasses (e.g., sunglasses) frame. The support structure 102 contains or otherwise includes various components to facilitate the projection of such images toward the eye of the user, such as a laser projector, an optical scanner, and a waveguide. In some embodiments, the support structure 102 further includes various sensors, such as one or more front-facing cameras, rear-facing cameras, other light sensors, motion sensors, accelerometers, and the like. In some embodiments, the support structure 102 further includes one or more radio frequency (RF) interfaces or other wireless interfaces, such as a Bluetooth™ interface, a WiFi interface, and the like. Further, in some embodiments, the support structure 102 further includes one or more batteries or other portable power sources for supplying power to the electrical components of the display system 100. In some embodiments, some or all of these components of the display system 100 are fully or partially contained within an inner volume of support structure 102, such as within the arm 104 in region 112 of the support structure 102. It should be noted that while an example form factor is depicted, it will be appreciated that in other embodiments the display system 100 may have a different shape and appearance from the eyeglasses frame depicted in FIG. 1.

One or both of the lens elements 108, 110 are used by the display system 100 to provide an augmented reality (AR) display in which rendered graphical content can be superimposed over or otherwise provided in conjunction with a real-world view as perceived by the user through the lens elements 108, 110. For example, laser light used to form a perceptible image or series of images may be projected by a laser projector of the display system 100 onto the eye of the user via a series of optical elements, such as a waveguide formed at least partially in the corresponding lens element, one or more scan mirrors, and one or more optical relays. One or both of the lens elements 108, 110 thus include at least a portion of a waveguide that routes display light received by an incoupler of the waveguide to an outcoupler of the waveguide, which outputs the display light toward an eye of a user of the display system 100. The display light is modulated and scanned onto the eye of the user such that the user perceives the display light as an image. In addition, each of the lens elements 108, 110 is sufficiently transparent to allow a user to see through the lens elements to provide a field of view of the user's real-world environment such that the image appears superimposed over at least a portion of the real-world environment.

In some embodiments, the projector is a digital light processing-based projector, a scanning laser projector, or any combination of a modulative light source such as a laser or one or more LEDs and a dynamic reflector mechanism such as one or more dynamic scanners or digital light processors. In some embodiments, the projector includes multiple laser diodes (e.g., a red laser diode, a green laser diode, and/or a blue laser diode) and at least one scan mirror (e.g., two one-dimensional scan mirrors, which may be micro-electromechanical system (MEMS)-based or piezo-based). The projector is communicatively coupled to the controller and a non-transitory processor-readable storage medium or memory storing processor-executable instructions and other data that, when executed by the controller, cause the controller to control the operation of the projector. In some embodiments, the controller controls a scan area size and scan area location for the projector and is communicatively coupled to a processor (not shown) that generates content to be displayed at the display system 100. The projector scans light over a variable area, designated the FOV area 106, of the display system 100. The scan area size corresponds to the size of the FOV area 106, and the scan area location corresponds to a region of one of the lens elements 108, 110 at which the FOV area 106 is visible to the user. Generally, it is desirable for a display to have a wide FOV to accommodate the outcoupling of light across a wide range of angles. Herein, the range of different user eye positions that will be able to see the display is referred to as the eyebox of the display.

In some embodiments, the projector routes light via first and second scan mirrors, an optical relay disposed between the first and second scan mirrors, and a waveguide disposed at the output of the second scan mirror. In some embodiments, at least a portion of an outcoupler of the waveguide may overlap the FOV area 106.

In some embodiments, the projector is an LBS display system projector with a laser controller configured to control one or more lasers to emit light for displaying an image or a series of images to the user via FOV area 106. The laser controller is configured to identify a pixel color display intensity (e.g., red pixel display intensity, green pixel display intensity, and blue pixel display intensity) for displaying the image on FOV area 106. The laser controller is further configured to identify a first laser drive level and a second laser drive level for each laser based on the identified pixel color display intensity. Furthermore, the laser controller is configured to control each laser to alternate between its respective first laser drive level and second laser drive level in a series of laser pulses to emit light at a duty-cycled intensity corresponding to the pixel color display intensity for displaying the image.

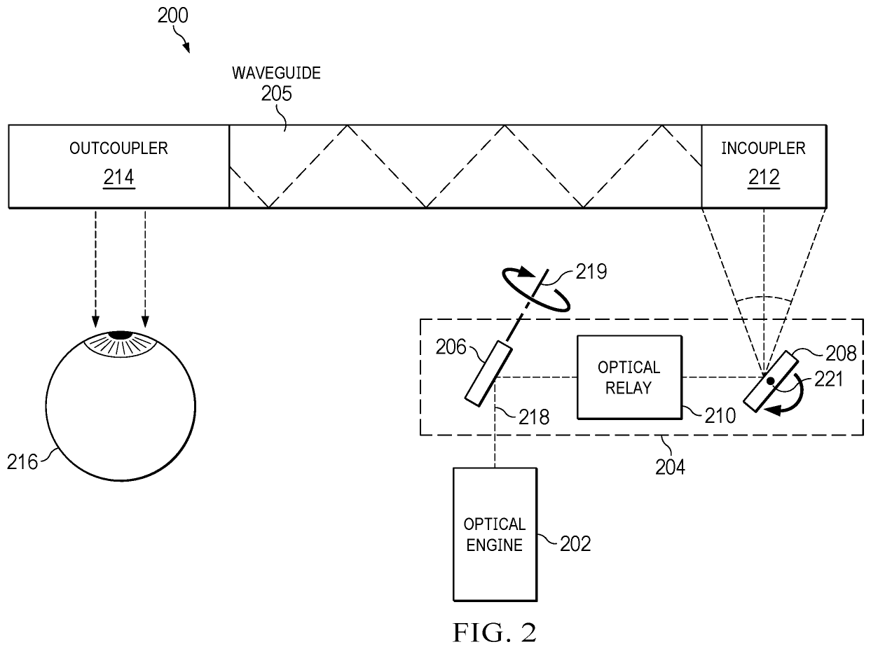

FIG. 2 illustrates a simplified block diagram of a laser projection system 200 that projects images directly onto the eye of a user via laser light. The laser projection system 200 includes an optical engine 202, an optical scanner 204, and a waveguide 205. The optical scanner 204 includes a first scan mirror 206, a second scan mirror 208, and an optical relay 210. The waveguide 205 includes an incoupler 212 and an outcoupler 214, with the outcoupler 214 being optically aligned with an eye 216 of a user in the present example. In some embodiments, the laser projection system 200 is implemented in a wearable heads-up display or other display system, such as the display system 100 of FIG. 1.

The optical engine 202 includes one or more laser light sources configured to generate and output laser light 218 (e.g., visible laser light such as red, blue, and green laser light and/or non-visible laser light such as infrared laser light). In some embodiments, the optical engine 202 is coupled to a driver or other controller, e.g., a laser controller (not shown), which controls the timing and/or intensity of emission of laser light from the laser light sources of the optical engine 202 in accordance with instructions received by the controller or driver from a computer processor coupled thereto to modulate the laser light 218 to be perceived as images when output to the retina of an eye 216 of a user. In some embodiments, the laser controller determines a pixel display intensity for each laser color based on an image to be displayed to the user. For example, the laser controller identifies a red pixel display intensity for the red laser to emit the red light portion of the image, a blue pixel display intensity for the blue laser to emit the blue light portion of the image, and a green pixel display intensity for the green laser to emit the green light portion of the image. The laser controller identifies a first laser drive level and a second laser drive level for each respective laser based on the respective pixel display intensity. The laser controller then controls the respective laser to alternate between its first and the second laser drive levels in a series of laser pulses to emit light at a duty-cycled intensity corresponding to the respective pixel display intensity.

For example, during the operation of the laser projection system 200, multiple laser light beams having respectively different wavelengths are output by the laser light sources of the optical engine 202, then combined via a beam combiner (not shown), before being directed to the eye 216 of the user. The optical engine 202 modulates the respective intensities of the laser light beams so that the combined laser light reflects a series of pixels of an image, with the particular intensity of each laser light beam at any given point in time contributing to the amount of corresponding color content and brightness in the pixel being represented by the combined laser light at that time.

One or both of the scan mirrors 206 and 208 of the optical scanner 204 are MEMS mirrors in some embodiments. For example, the scan mirror 206 and the scan mirror 208 are MEMS mirrors that are driven by respective actuation voltages to oscillate during active operation of the laser projection system 200, causing the scan mirrors 206 and 208 to scan the laser light 218. Oscillation of the scan mirror 206 causes laser light 218 output by the optical engine 202 to be scanned through the optical relay 210 and across a surface of the second scan mirror 208. The second scan mirror 208 scans the laser light 218 received from the scan mirror 206 toward an incoupler 212 of the waveguide 205. In some embodiments, the scan mirror 206 oscillates along a first scanning axis 219, such that the laser light 218 is scanned in only one dimension (i.e., in a line) across the surface of the second scan mirror 208. In some embodiments, the scan mirror 208 oscillates or otherwise rotates along a second scanning axis 221. In some embodiments, the first scanning axis 219 is perpendicular to the second scanning axis 221.

In some embodiments, the incoupler 212 has a substantially rectangular profile and is configured to receive the laser light 218 and direct the laser light 218 into the waveguide 205. The incoupler 212 is defined by a smaller dimension (i.e., width) and a larger orthogonal dimension (i.e., length). In an embodiment, the optical relay 210 is a line-scan optical relay that receives the laser light 218 scanned in a first dimension by the first scan mirror 206 (e.g., the first dimension corresponding to the small dimension of the incoupler 212), routes the laser light 218 to the second scan mirror 208, and introduces a convergence to the laser light 218 in the first dimension to an exit pupil beyond the second scan mirror 208. Herein, an “exit pupil” in an optical system refers to the location along the optical path where beams of light intersect. For example, the possible optical paths of the laser light 218, following reflection by the first scan mirror 206, are initially spread along the first scanning axis, but later these paths intersect at an exit pupil beyond the second scan mirror 208 due to convergence introduced by the optical relay 210. For example, the width (i.e., smallest dimension) of a given exit pupil approximately corresponds to the diameter of the laser light corresponding to that exit pupil. Accordingly, the exit pupil can be considered a “virtual aperture.” According to various embodiments, the optical relay 210 includes one or more collimation lenses that shape and focus the laser light 218 on the second scan mirror 208 or includes a molded reflective relay that includes two or more spherical, aspheric, parabolic, and/or freeform lenses that shape and direct the laser light 218 onto the second scan mirror 208. The second scan mirror 208 receives the laser light 218 and scans the laser light 218 in a second dimension, the second dimension corresponding to the long dimension of the incoupler 212 of the waveguide 205. In some embodiments, the second scan mirror 208 causes the exit pupil of the laser light 218 to be swept along a line along the second dimension. In some embodiments, the incoupler 212 is positioned at or near the swept line downstream from the second scan mirror 208 such that the second scan mirror 208 scans the laser light 218 as a line or row over the incoupler 212.

In some embodiments, the optical engine 202 includes an edge-emitting laser (EEL) that emits a laser light 218 having a substantially elliptical, non-circular cross-section, and the optical relay 210 magnifies or minimizes the laser light 218 along its semi-major or semi-minor axis to circularize the laser light 218 prior to convergence of the laser light 218 on the second scan mirror 208. In some such embodiments, a surface of a mirror plate of the scan mirror 206 is elliptical and non-circular (e.g., similar in shape and size to the cross-sectional area of the laser light 218). In other such embodiments, the surface of the mirror plate of the scan mirror 206 is circular.

The waveguide 205 of the laser projection system 200 includes the incoupler 212 and the outcoupler 214. The term “waveguide,” as used herein, will be understood to mean a combiner using one or more of total internal reflection (TIR), specialized filters, and/or reflective surfaces, to transfer light from an incoupler (such as the incoupler 212) to an outcoupler (such as the outcoupler 214). In some display applications, the light is a collimated image, and the waveguide transfers and replicates the collimated image to the eye. In general, the terms “incoupler” and “outcoupler” will be understood to refer to any type of optical grating structure, including, but not limited to, diffraction gratings (e.g., binary diffractive gratings), holograms, holographic optical elements (e.g., optical elements using one or more holograms), volume diffraction gratings, volume holograms, surface relief diffraction gratings, and/or surface relief holograms. In some embodiments, a given incoupler or outcoupler is configured as a transmissive grating (e.g., a transmissive diffraction grating or a transmissive holographic grating) that causes the incoupler or outcoupler to transmit light and to apply designed optical function(s) to the light during the transmission. In some embodiments, a given incoupler or outcoupler is a reflective grating (e.g., a reflective diffraction grating or a reflective holographic grating) that causes the incoupler or outcoupler to reflect light and to apply designed optical function(s) to the light during the reflection. In the present example, the laser light 218 received at the incoupler 212 is relayed to the outcoupler 214 via the waveguide 205 using TIR. The laser light 218 is then output to the eye 216 of a user via the outcoupler 214. As described above, in some embodiments the waveguide 205 is implemented as part of an eyeglass lens, such as the lens 108 or lens 110 (FIG. 1) of the display system having an eyeglass form factor and employing the laser projection system 200.

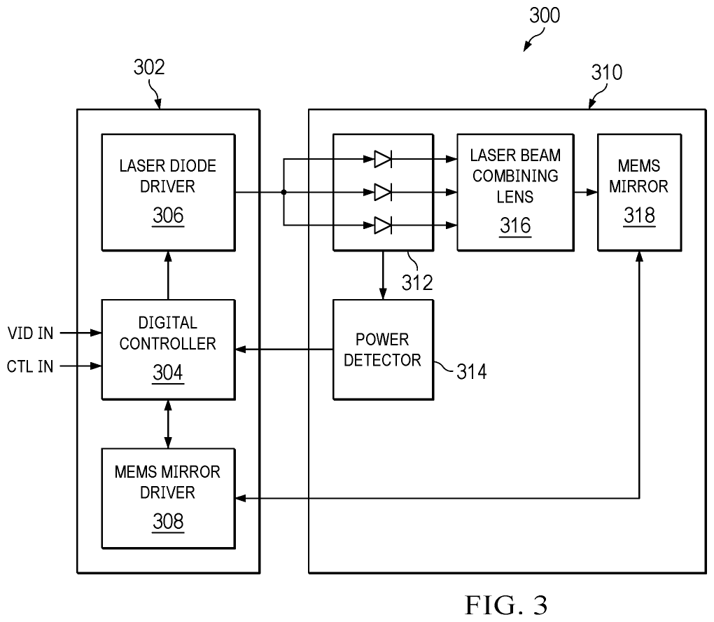

FIG. 3 shows an example of a block diagram of an LBS display system 300 in accordance with some embodiments. The LBS display system 300 includes an electronic subsystem 302 and an optical subsystem 310. The electronic subsystem 302 includes a digital controller 304, a laser diode driver (LDD) 306, and a micro-electromechanical system (MEMS) mirror driver 308, and the optical subsystem 310 includes the lasers 312, a power detector 314, one or more laser beam combining lenses 316, and a MEMS mirror 318.

The electronic subsystem 302 components include hardware and software and/or firmware that configure the hardware, are executed by the hardware, and/or are otherwise associated with the hardware. For example, the electronic subsystem 302 components include physical electronic components such as programmable circuitry and a corresponding memory storing software and/or firmware for executing the techniques described herein. In some embodiments, the programmable circuitry includes one or more instances of application-specific integrated circuits, field programmable gate arrays, or other types of programmable logic devices.

The digital controller 304 receives video input (VID IN) and control input (CTL IN) for displaying an image or series of images to a user of a display system (such as one corresponding to 100 in FIG. 1). The digital controller 304 executes operations and controls the other components of the LBS display system 300 to display the image or the series of images. In some embodiments, the digital controller 304 executes video processing operations, distortion precompensation operations, control loop operations, calibration operations, LDD modulation operations, temperature/pressure compensation operations, and other operations associated with the overall control of LBS display system 300. For example, the digital controller 304 includes hardware and software to control the oscillations and to calibrate the MEMS mirror 318. In another example, the digital controller 304 includes hardware and software to control the lasers 312 by modulating the amount of current output by the LDD 306 based on the video input and/or control input.

The LDD 306 operates as a current source for the lasers 312 by receiving command signals from the digital controller 304 associated with images to be displayed and delivering current to the lasers 312 based on these command signals. In some embodiments, the current is constant. In other embodiments, the current alternates between different levels. For example, the LDD 306 utilizes n-bit (where n is an integer) laser diode drive levels (also referred to as laser drive levels) for controlling the input current delivered to the lasers 312. In some embodiments, the LDD 306 is configured to identify a laser drive level for the lasers 312 based on the pixel display intensity for displaying an image from the video input to the digital controller 304. The laser drive level is associated, for example, with an input current delivered by the LDD 306 to the lasers 312. In some embodiments, the LDD 306 retrieves the laser drive level from a lookup table (LUT) storing values for a plurality of laser drive levels and their corresponding pixel display intensities. In some embodiments, the LDD 306 retrieves the two laser drive levels for each laser from the LUT and a duty cycle value and controls each of the lasers 312 to alternate between the respective two laser drive levels by alternating the current delivered to each of the lasers 312. In this manner, the LDD 306 controls each of the lasers 312 to emit light at a duty-cycled intensity corresponding to the pixel display intensity of the image. For example, the LDD 306 controlling a red laser to operate at a 50% duty cycle will control the red laser of lasers 312 to operate at the first laser drive level for half the time of the duty cycle and to operate at a second laser drive level the other half the time of the duty cycle. In another example, the LDD instructing a blue laser to operate at a 75% duty cycle will control the blue laser to operate at a first laser drive level for a quarter of the time of the duty cycle, and a second (and higher) laser drive level for the other three-quarters of the time of the duty cycle. Accordingly, the LDD 306, in conjunction with the instructions received from the digital controller 304, operates as a laser controller for the LBS display system 300.

The MEMS mirror driver 308 includes electrostatic, magnetic, and/or piezo drivers, for example, to operate the MEMS mirror 318. In some embodiments, the MEMS mirror 318 corresponds with at least one of scan mirrors 206 and/or 208 in FIG. 2. For example, the MEMS mirror driver 308 controls the MEMS mirror 318 to oscillate or rotate along a scanning axis such as one corresponding to 219 or 221 shown in FIG. 2.

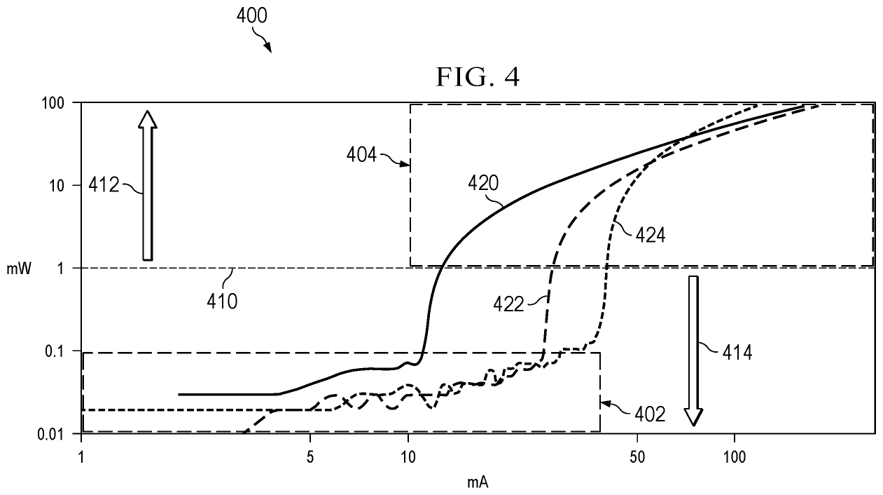

Referring to the optical subsystem 310, in some embodiments, the lasers 312 include red, green, and blue (RGB) lasers. The output intensity of each of the lasers 312 is a function of the input current delivered by the LDD 306 (described in further detail in FIG. 4). In some embodiments, the LDD 306 is configured to deliver a different input current to each of the lasers 312. Accordingly, for example, a first laser of the lasers 312, such as a red laser, is controlled to emit light of a higher intensity than a second laser of the laser 312, such as a green or blue laser. The one or more laser beam combining lenses 316 receive and combine the laser beams emitted from the lasers 312 and pass the combined laser beams to the MEMS mirror 318. For example, the laser beam combining lenses 316 include a plurality of transmissive and/or reflective elements for receiving the laser beams, combining the laser beams (e.g., collimating the laser beams), and directing the combined laser beams toward the MEMS mirror 318. In some embodiments, the plurality of transmissive and/or reflective elements include dichroic mirrors or beam splitters, reflective mirrors, and/or optical prisms, for example. MEMS mirror 318 then redirects the combined laser beams toward a further component of the display system, such as the incoupler 212 of the waveguide 205 in FIG. 2. The power detector 314 is configured to monitor the power of the lasers 312 and provide feedback to the digital controller 304. This feedback is used to improve the overall operation of the LBS display system 300.

FIG. 4 shows an example of a graph 400 illustrating the relationship between the laser input current (in mA) on the x-axis to the laser output intensity (in mW) on the y-axis in accordance with some embodiments. The hardware of the LDD 306, for example, maps the output color intensity for each laser to a laser drive level that is associated with an input current. In graph 400, examples of laser light-current curves are shown for a blue laser 420, a green laser 422, and a red laser 424.

The controlling of the laser drive levels is constrained by the physics of the lasers. The controlling of the lasers can be split into a spontaneous emission region 402 and a stimulated emission region 404. A cutoff line 410 is illustrated at the low-end of the stimulated emission region 404 and marks the boundary between the stable region 412 and the unstable region 414. The intersection points along each of curves 420-424 at the cutoff line 410 correspond to the minimum laser operation thresholds for operating the respective laser in the stable region 412. The laser drive level corresponding to the minimum laser operation threshold for each laser is referred to as the minimum laser drive level for that laser.

As shown in graph 400, the stimulated emission region 404 in the stable region 412 is characterized by a linear relationship between the input current and the output intensity of the respective lasers. The spontaneous emission region 402 in the unstable region 414 does not follow this relationship. Conventional LBS display systems do not operate the laser in unstable region 414 due to the instability of the lasers and only operate in the stable region 412 with dynamic range in output intensity of about 80:1. In some embodiments, the techniques presented herein expand the dynamic range up to about 600:1 by controlling the lasers to mimic operation in the unstable region 414 by alternating between a first laser drive level corresponding to the minimum laser operation threshold and a second laser drive level corresponding to a non-lasing state in which the laser does not emit light. By quickly alternating between the first and second laser drive levels in successive laser pulses, the LBS system is able to deliver, as perceived by the user, an image with an output intensity that appears to fall within the unstable range 414. In other words, the LBS display systems presented herein utilize dithering techniques between two lasing states to alternate the pixel intensities from frame-to-frame to approximate the target pixel intensity over time. In this manner, the techniques of this disclosure expand the dynamic range of the output intensity of the LBS display system.

To illustrate, and by way of example, a first laser of the LBS system has a minimum laser operation threshold that is 10% of its maximum laser power intensity. Conventional LBS display systems, therefore, would only be able to control the laser to display images at or above this 10% threshold. However, the LBS display system of the present disclosure provides techniques to display images, as perceived by the user, which fall below this 10% threshold. The laser controller does this by controlling the laser to alternate between a first laser drive level corresponding to the minimum laser drive level threshold and a second laser drive level corresponding to a non-lasing state. In other words, the laser controller controls the laser to operate in a duty cycle by emitting laser light at the first laser drive level for a first portion of the duty cycle and at the second laser drive level for the second portion of the duty cycle. For example, the laser controller controls the laser to emit light at an output intensity, as perceived by the user, that falls at 5% of the maximum laser drive intensity by controlling the laser to operate at a 50% duty cycle alternating between the minimum laser drive level threshold (i.e., 10% of the maximum laser power intensity) and the non-lasing state (i.e., no light). Accordingly, the laser controller implements dithering techniques across a series of frames to approximate the target pixel display intensity, i.e., 5% in this example, over time

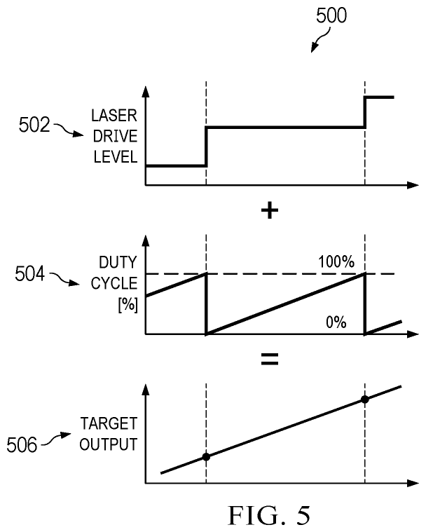

FIGS. 5-7 show considerations and techniques for dithering between two laser drive levels to achieve a duty-cycled intensity corresponding to a pixel display intensity in the stable region 412. Accordingly, the color depth of the image provided to the user is increased, thereby improving the end user experience.

FIG. 5 shows examples of a series of graphs 502-506 illustrating the relationship between the laser drive levels 502, duty cycle percentage 504, and the target output 506 of a pixel intensity falling in the stable region 412 in accordance with some embodiments.

The target output 506 of the pixel display intensity for displaying an image to the user is illustrated graphically as having two components: a laser drive level component 502 with integer levels that increase monotonically and a duty cycle component 504 ranging from 0-100% between each laser drive level. The target output 506 is achieved by combining the integer laser drive levels 502 with the fractional duty cycle 504. In some embodiments, a laser diode driver (LDD), such as one corresponding to LDD 306 in FIG. 3, implements a linear dither machine that alternates between a base drive level (also referred to as the second laser drive level) and the dither level (also referred to as the first laser drive level) using the corresponding duty cycle. These two levels are one drive level apart, i.e., dither level-1=base drive level, and the relationship in output intensity to laser diode drive level between the two levels is assumed to be linear, i.e., has a constant slope as shown in graph 506.

In some embodiments, the lasers, such as the lasers 312 shown in FIG. 3, accept a 10 bit laser drive level ranging from 0-1023. Additionally, in some embodiments, there are 64 k (16 bit) of possible pixel intensities generated for displaying images to a user of a WMHD. In some embodiments, a lookup table (LUT) is used to achieve the mapping between the pixel intensity and the laser drive level. For example, the LUT includes 512 entries and provides values for the laser drive levels and the duty cycle. The duty cycle is provided by the fractional units between the laser drive levels. In other words, the duty cycle is used to achieve the fractional values between two adjacent drive levels. For example, say a target pixel display intensity for displaying an image to a user is mapped to a laser drive level of 2.5. Since the laser drive levels are integer values, the LDD controls the laser to operate at a laser drive level of 2 for half the time and at a laser drive level of 3 for the other half of the time to create “the appearance” of a laser drive level of 2.5.

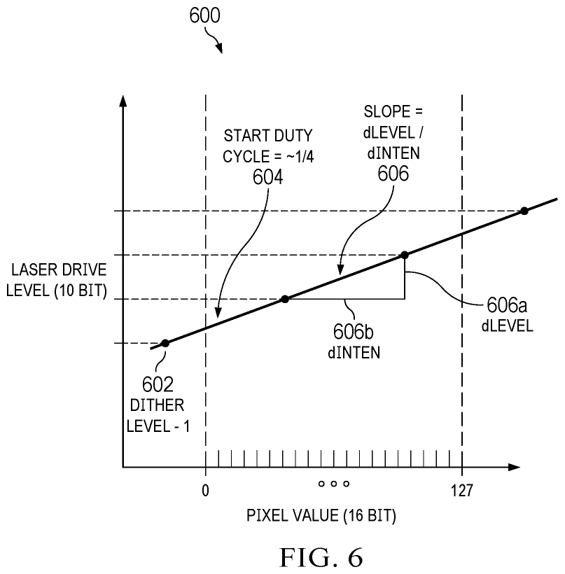

Accordingly, to implement dither in the stable region 412, the hardware of the laser controller stores information in the LUT. In some embodiments, this information includes detailing the different laser drive levels, start duty cycles, and a slope value (dLevel/dInten) for the linear relationship between the different laser drive levels and the associated output intensities. In some embodiments, the LUT only stores the base drive level as the dither level can be determined since it is one level above the base drive level, i.e., dither level-1=base drive level. The start duty cycle accounts for situations where a given LDD LUT entry does not start on a drive level border. The dLevel/dInten is the slope of the laser drive level to pixel intensity relationship. These parameters are all illustrated by way of example in graph 600 of FIG. 6.

FIG. 6 shows a graph 600 illustrating the above discussed dither parameters that are stored in a LUT, according to some embodiments. The x-axis represents the pixel intensity values, and the y-axis represents the laser drive levels.

More specifically, graph 600 shows the aforementioned dither level-1 602 (i.e., base level), the start duty cycle 604, and the slope (dLevel/dInten) 606 with two components dLevel 606a and dInten 606b. For example, if the start cycle is about 25%, the starting dither intensity is about 25%. The dither-1 level 602 corresponds to the lower of the two laser drive levels at which the LDD controls the laser to operate at in the duty cycle. The other two parameters (the start duty cycle 604 and the slope 606) are used to calculate the duty cycle used by the laser controller for alternating between the dither-1 level 602 (i.e., base level) and the dither level (not shown).

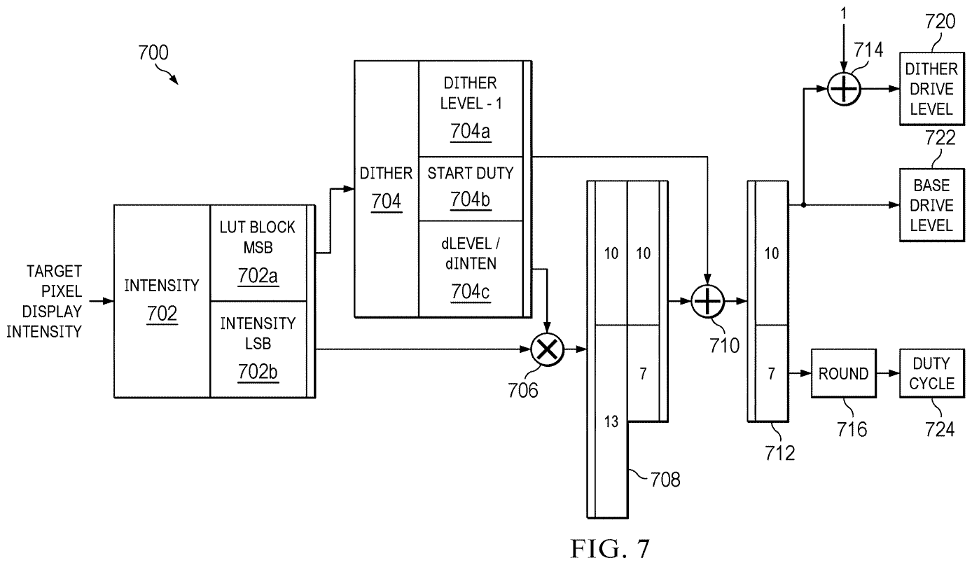

FIG. 7 shows an example of a block diagram of a dither pipeline 700 for determining a dither drive level (also referred to as first laser drive level) 720, a base drive level (also referred to as a second laser drive level) 722, and a duty cycle 724 in accordance with some embodiments. In some embodiments, the dither pipeline 700 is implemented via a combination of laser controller hardware such as programmable circuitry with software and/or firmware. The dither pipeline 700 receives the target pixel display intensity and based on this target pixel display intensity, outputs the first and second laser drive levels (i.e., the dither drive level 720 and the base drive level 722) as well as the duty cycle 724 for emitting light at a duty-cycled intensity. The values shown in dither pipeline diagram 700 indicate the number of bits.

The target pixel display intensity is received at intensity stage 702 based on an image to be displayed to a user. The target pixel display intensity is split into two components. The first component is a most significant bit (MSB) component 702a that represents the “integer” portion of the laser drive level. In some embodiments, the MSB portion 702a is used for identifying a dither level-1 component 704a (i.e., base drive level) from LUT 704. The second component is a least significant bit (LSB) component 702b that represents a fractional portion of the laser drive level. For example, given a 16-bit input target pixel display intensity, the top 10 bits (i.e., MSB) represent the integer portion and the bottom 6 bits (i.e., LSB) represent the fractional portion. The dither LUT provides information related to the dither-1 704a (i.e., base drive level), the start duty cycle 704b, and the dLevel/dInten 704c (i.e., the slope of the relationship of the drive levels to intensity in the stable region).

To illustrate by way of example, consider a 16-bit target pixel display intensity of 40,500 is received at stage 702. In binary, this is 1001111000110100₂ (where x₂ represents base 2). The 10 MSB, therefore, are 1001111000₂(632₁₀ , where x₁₀ represents base 10). The lower six bits are 110100₂(52₁₀ ). The full range of the LSB is 2⁶, or 64, so the LSB portion 702b corresponds to a 52/64“fraction.” In this manner, the 40,500 target pixel intensity value received at 702 is mapped to an integer drive level of 632 and a fraction of 52/64.

At stage 706, the mapping of this fraction portion to the laser drive level is performed based on the linear relationship of the laser drive level to intensity within the stable region. The slope (dLevel/dInten) 704c is used to find a laser drive level this fractional value 702b corresponds to. So, since the relationship between the intensity and the laser drive level is linear, the fractional value of the intensity 702b is multiplied by the slope 704c to produce a laser drive level corresponding to the fractional value.

At 708, in some embodiments, the product 708 resulting from stage 706 is truncated to account for the laser driver hardware. The lower bits of the resulting product from stage 706 represent more accuracy in the fractional component than can be represented by the laser drive hardware (e.g., with 26 fractional levels), so the product is truncated from further processing.

Referring to stage 710, recall that the mapping to the laser drive level may not directly align with the laser drive level integer boundaries. The integer level is represented by the dither level-1 704a (i.e., the base laser drive level) and the fraction value is represented by the start duty cycle 704b, i.e., corresponding to the value at the starting point shown at 604 in FIG. 6. The truncated fractional component from 708 is added at stage 710 to the dither level-1 704a and the start duty cycle 704b to get the desired laser drive level 712. In some embodiments, this desired laser drive level 712 is more bits than the laser driver. For example, the desired laser drive level 712 is 17 bits, and the laser drive level is configured with 10 bits of laser drive levels. The top 10 bits of the desired laser drive level 712 provide the base drive level 722. Adding 1 to the top 10 bits of the desired laser drive level 712 at stage 714 provides the dither drive level in 720 (recall, the dither drive level is 1 more than the base drive level). The bottom 7 bits of the desired laser drive level 712 are rounded to 6 bits and used to represent the fractional component corresponding to a duty cycle with which we alternate between the base drive level 722 and the dither drive level 720.

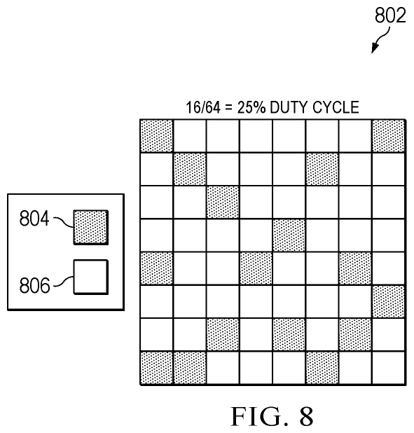

FIG. 8 shows an example of a dither tile 802 for implementing a duty cycle (e.g., corresponding to duty cycle 724 in FIG. 7) to a grid of pixels in accordance with some embodiments. The duty cycle corresponds to the amount of time that a given pixel is “on” (i.e., at the dither level or the first laser drive level) or “off” (i.e., at the base level or the second laser drive level).

In some embodiments, these “on” or “off” states are achieved by mapping dither tiles to pixels of an image display region of a WHMD. In some embodiments, the dither tile is a 32×32 bit tile or a tile of another size. For example, the dither tile 802 shown in FIG. 8 is an 8 ×8 bit tile with a 25% duty cycle. The shaded tiles 804 correspond to the pixel represented by that respective tile being in the “on” state, and the light tiles 806 correspond to the pixel represented by that respective tile being in the “off” state. In this manner, each bit in the tile describes whether the laser drive level for a pixel at that location is to be increased or not to achieve the given intermediate intensity between two laser drive levels.

To illustrate, and by way of example, in some cases the target output is a large, flat output such as at intensity 700.5 (in the stable range). The fractional portion (0.5) corresponds to a 50% duty cycle. The decision for which pixels to move to laser drive level 701 and which to leave at laser drive level 700 at dictated by the dither tile with 50% of the tiles in the “on” state (i.e., at level 701) and 50% in the “off” state (i.e., at level 700).

In some embodiments, the dither tiles are referred to as noise masks and represent a grid of Boolean values that follows a noise distribution. The number of true values within the grid corresponds to the duty cycle percentage. For example, in FIG. 8, there are 16 true values in the 8×8 pixel grid to provide a duty cycle of 25%. In a system with n noise masks, where n is an integer, the duty cycle of the noise masks increases from 1/n to 1 in increments of 1/n. The noise masks are generated such that the true values are equally spaced, i.e., the noise frequency distribution avoids both low and high frequency noise. This is referred to as blue noise. In some embodiments, noise masks are generated so that the spatial dither does not result in loss of information by clamping to a minimum duty cycle. In some embodiments, the masks are selected such that the minimum user interface (UI) stroke width results in at least one laser pulse.

Each noise mask is an m x m grid of Boolean values, where m is an integer. Any pixel being drawn has a corresponding (x, y) position in the grid, and the noise masks are tiled across the entirety of the image display region, i.e., region corresponding to FOV area 106, such that any position (x, y) in the image display region corresponds to a position in one of the tiled m x m grids of Boolean values. Accordingly, the noise mask encodes information to determine whether the output for the given pixel will be at the base level (i.e., second laser drive level) or the dither level (i.e., first laser drive level).

The use of the dither tiles (i.e., noise masks) provides a mechanism for spatial dither, where the same amount of pixel intensity values at different positions in the image display region have different outputs. However, this same output intensity and positioning of the noise masks may result in noticeable patterns in the displayed image or in never drawing a pixel, which undesirably filters information from the displayed image. Accordingly, to address this, temporal dither techniques are implemented to supplement the spatial dither techniques by varying the dither tiles over time.

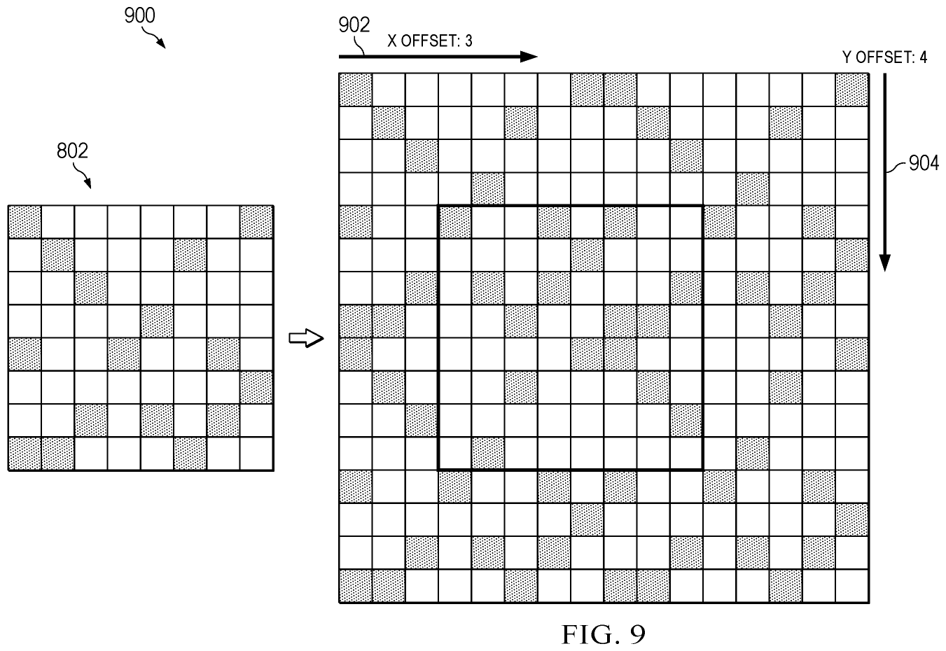

FIG. 9 shows an example of a temporal dither technique 900 in accordance with some embodiments. The temporal dither is applied via a random walk vector. To implement the random walk, a set of {x, y} offsets are stored. These offsets result in a shift applied to each coordinate of the noise masks. Given a random distribution in the original dither tile and a random offset, each pixel will move from the base state (i.e., second laser drive level) and dither state (i.e., first laser drive level) at a rate proportional to the duty cycle. For example, as shown in FIG. 9, the random walk is applied with an offset of 3 in the x-direction 902 and an offset of 4 in the y-direction 904. In some embodiments, the offsets are applied for each subsequent laser pulse in a series of laser pulses.

In some embodiments, the offsets are generated randomly. Each subsequent laser pulse increments the random walk vector so that each laser pulse has a different offset in the (x, y) direction. The random walk applies a shift in both the x and y directions for each pulse such that the position (in the noise mask) is given by (x+x_{walk}, y+y_{walk}).

The width of each element in the random walk is log₂(m)*2. For example, considering a 32×32 noise mask (i.e., dither tile), log₂(32)=5, which corresponds to 32 potential offset values (0-31). This implies that the full range of the noise mask can be offset. Since there are two dimensions for the noise mask, these are joined together in a {5 bit x, 5 bit y} offset. This is one element in the offset vector. In some embodiments, the number of elements in the random walk vector is scalable to any quantity. For example, the number of elements in the random walk vector can be in the range of 10,000 elements.

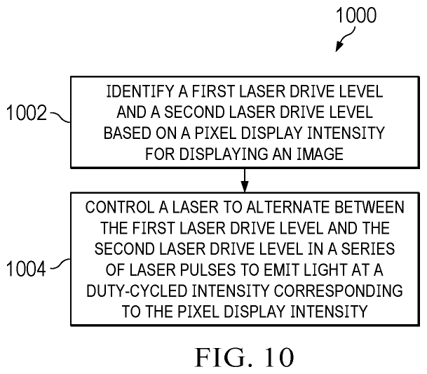

FIG. 10 shows a process flowchart 1000 illustrating a method to control a laser in an LBS display system of a WHMD in accordance with some embodiments. By controlling the laser in the manner shown in flowchart 1000, the laser controller of a LBS display system implements dithering techniques across a series of frames to approximate the target pixel display intensity over time for an image to be displayed to a user. The laser drive levels are alternated at a rate such that the user is unable to perceive the switches in laser drive levels and perceives the image resulting from the duty-cycled intensity as if the image were being displayed at the target pixel display intensity.

In 1002, the method includes identifying a first laser drive level and a second laser drive level based on a pixel display intensity for displaying an image. In some embodiments, the first laser drive level corresponds to a laser diode drive level and the second laser drive level corresponds to a second laser diode drive level lower than the first laser diode drive level. In some embodiments, the first laser drive level is one level higher than the second laser drive level. In other embodiments, the first laser drive level corresponds to a minimum laser drive level for operating in the stable region and the second laser drive level corresponds to a non-lasing state where the laser does not emit light. In some embodiments, the method includes retrieving the first laser drive level and the second laser drive level from a lookup table storing values for a plurality of laser drive levels and corresponding pixel display intensities. In some embodiments, the method includes identifying the first laser drive level and the second laser drive level from the lookup table based on the first laser drive level having a corresponding first pixel display intensity above the pixel display intensity and the second laser drive level having a corresponding second pixel display intensity below the pixel display intensity.

In 1004, the method includes controlling a laser to alternate between the first laser drive level and the second laser drive level in a series of laser pulses to emit light at a duty-cycled intensity corresponding to the pixel display intensity. In some embodiments, emitting light at the duty-cycled intensity comprises operating the laser at the first laser drive level for a first period of a duty cycle and operating the laser at the second drive level for a second period of the duty cycle, wherein a duration of the first portion relative to a duration of the second portion produces the duty-cycled intensity corresponding to the pixel display intensity. In some embodiments, the duty cycle corresponds to a noise mask selected from a table of noise masks, wherein the noise mask comprises a grid mapped to pixels in an image display area of the WHMD, and wherein the grid comprises a first subset of values corresponding to the first laser drive level and a second subset of values corresponding to the second laser drive level. In some embodiments, the method includes shifting the noise mask by an offset in at least one of a first direction or a second direction of the image display area for each laser pulse of the laser.

In some embodiments, certain aspects of the techniques described above may be implemented by one or more processors of a processing system executing software. The software comprises one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory) or coupled to the computer system via a wired or wireless network (e.g., network accessible storage (NAS)).

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

1. A laser controller for a wearable head mounted display (WHMD), the laser controller configured to:
identify a first laser drive level and a second laser drive level based on a pixel display intensity for displaying an image; and
control a laser to alternate between the first laser drive level and the second laser drive level in a series of laser pulses to emit light at a duty-cycled intensity corresponding to the pixel display intensity.

2. The laser controller of claim 1, further configured to retrieve at least one of the first laser drive level or the second laser drive level from a lookup table storing values for a plurality of laser drive levels and corresponding pixel display intensities.

3. The laser controller of claim 2, wherein at least one of the first laser drive level or the second laser drive level are identified from the lookup table based on the first laser drive level having a corresponding first pixel display intensity above the pixel display intensity or the second laser drive level having a corresponding second pixel display intensity below the pixel display intensity.

4. The laser controller of claim 3, wherein emitting light at the duty-cycled intensity comprises operating the laser at the first laser drive level for a first non-contiguous portion of a duty cycle and operating the laser at the second drive level for a second non-contiguous portion of the duty cycle, wherein a duration of the first non-contiguous portion relative to a duration of the second non-contiguous portion produces the duty-cycled intensity corresponding to the pixel display intensity.

5. The laser controller of claim 4, wherein the duration of the first non-contiguous portion and the duration of the second non-contiguous portion are equal.

6. The laser controller of claim 4, wherein the duration of the first non-contiguous portion and the duration of the second non-contiguous portion are not equal.

7. The laser controller of claim 3, wherein the duty cycle corresponds to a noise mask selected from a table of noise masks, wherein the noise mask comprises a grid mapped to pixels in an image display area of the WHMD, and wherein the grid comprises a first subset of values corresponding to the first laser drive level and a second subset of values corresponding to the second laser drive level.

8. The laser controller of claim 7, wherein the noise mask is tiled across the image display area.

9. The laser controller of claim 7, further configured to shift the noise mask by an offset in at least one of a first direction or a second direction of the image display area for subsequent laser pulses in the series of laser pulses.

10. The laser controller of claim 1, further configured to supply a current to the laser to control an output intensity of the laser, wherein a laser drive level of the laser is split into a first region characterized by a linear relationship between the supply current and the output intensity and a second region below the first region that does not follow the linear relationship.

11. The laser controller of claim 10, further configured to control the laser to mimic operation of an output intensity in the second region by alternating between the first laser drive level and the second laser drive level, wherein the first laser drive level corresponds to a minimum laser drive level in the first region and the second laser drive level corresponds to a non-lasing state in which the laser does not emit light.

12. A laser beam scanner for a wearable head mounted display (WHMD), the laser beam scanner comprising:
one or more lasers each configured to emit light of a particular color; and
a laser controller configured to:
identify, for at least one of the one or more lasers, a first laser drive level and a second laser drive level based on a pixel display intensity for displaying an image; and
control the at least one of the one or more lasers to alternate between the first laser drive level and the second laser drive level in a series of laser pulses to emit light at a duty-cycled intensity corresponding to the pixel display intensity.

13. The laser beam scanner of claim 12, wherein at least one of the first laser drive level or the second laser drive level are identified from the a lookup table based on the first laser drive level having a corresponding first pixel display intensity above the pixel display intensity and the second laser drive level having a corresponding second pixel display intensity below the pixel display intensity.

14. The laser beam scanner of claim 13, wherein emitting light at the duty-cycled intensity comprises operating the at least one of the one or more lasers at the first laser drive level for a first period of a duty cycle and operating the at least one of the one or more lasers at the second drive level for a second period of the duty cycle, wherein a duration of the first period relative to a duration of the second period produces the duty-cycled intensity corresponding to the pixel display intensity.

15. The laser beam scanner of claim 14, wherein the duty cycle corresponds to a noise mask selected from a table of noise masks, wherein the noise mask comprises a grid mapped to pixels in an image display area of the WHMD, and wherein the grid comprises a first subset of values corresponding to the first laser drive level and a second subset of values corresponding to the second laser drive level.

16. The laser beam scanner of claim 15, wherein the laser controller is configured to shift the noise mask by an offset in at least one of a first direction or a second direction of the image display area for subsequent laser pulses in the series of laser pulses.

17. A method comprising:
identifying a first laser drive level and a second laser drive level based on a pixel display intensity for displaying an image; and
controlling a laser to alternate between the first laser drive level and the second laser drive level in a series of laser pulses to emit light at a duty-cycled intensity corresponding to the pixel display intensity.

18. The method of claim 17, further comprising retrieving at least one of the first laser drive level or the second laser drive level from a lookup table storing values for a plurality of laser drive levels and corresponding pixel display intensities.

19. The method of claim 18, wherein the first laser drive level or the second laser drive level are identified from the lookup table based on the first laser drive level having a corresponding first pixel display intensity above the pixel display intensity or the second laser drive level having a corresponding second pixel display intensity below the pixel display intensity.

20. The method of claim 19, wherein displaying the image at the duty-cycled intensity comprises operating the laser at the first laser drive level for a first period of a duty cycle and operating the laser at the second drive level for a second period of the duty cycle, wherein a duration of the first period relative to a duration of the second portion period produces the duty-cycled intensity corresponding to the pixel display intensity.
